(19) United States
(12) Patent Application Publication
(10) Pub. No.: US 2026/0082623 A1
(43) Pub. Date: Mar. 19, 2026

(54) LDMOS TRANSISTOR AND ITS MANUFACTURING METHOD

(71) Applicant: Silergy Semiconductor Technology (Hangzhou) LTD, Hangzhou (CN)

(72) Inventors: Hui Yu, Hangzhou (CN); Jiajun Chen, Hangzhou (CN); Jun Cai, Hangzhou (CN)

(21) Appl. No.: 19/320,003

(22) Filed: Sep. 5, 2025

(30) Foreign Application Priority Data
Sep. 14, 2024 (CN) 202411295987.4

(51) Int. Cl. H10D 30/65; H10D 30/01; H10D 62/10

(52) U.S. Cl. CPC H10D 30/655; H10D 30/0281; H10D 62/109

(57) ABSTRACT

An LDMOS transistor can include: an intrinsic region and a termination region distributed along, where the intrinsic region includes a semiconductor region of a first doped type, a body region of a second doped type extending from the upper surface of the semiconductor region into the interior of the semiconductor region, a drift region located in the semiconductor region, the drift region including at least one first implant region of the first doped type and at least one second implant region of the second doped type, where the at least one second implant region is separated from the body region, a source region of the first doped type located in the body region, and a drain region of the first doped type located in the semiconductor region, where the termination region includes a third implant region of the second doped type being in contact with the second implant region.

### RELATED APPLICATIONS

This application claims the benefit of Chinese Patent Application No. 202411295987.4, filed on Sep. 14, 2024, which is incorporated herein by reference in its entirety.

### FIELD OF THE INVENTION

The present invention generally relates to the field of semiconductor technology, and more particularly to semiconductor devices including LDMOS transistors and methods of mailing LDMOS transistors.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1 is a cross-sectional view of an example LDMOS transistor.

FIG. 2 is a plan view of a first example LDMOS transistor, in accordance with embodiments of the present invention.

FIG. 3 is a cross-sectional view of an example intrinsic region of the first example LDMOS transistor, in accordance with embodiments of the present invention.

FIG. 4 is a cross-sectional view of an example termination region of the first example LDMOS transistor, in accordance with embodiments of the present invention.

FIG. 5 is a plan view of a second example LDMOS transistor, in accordance with embodiments of the present invention.

FIG. 6 is a cross-sectional view of an example intrinsic region of the second example LDMOS transistor, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Further, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die can be mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

High voltage and high current impose increasingly higher demands on laterally-diffused metal-oxide-semiconductor (LDMOS) transistors. On one hand, the chip area of high-current application products depends on the generation-by-generation reduction of specific on-resistance Rsp, placing high demands on the extreme optimization of breakdown voltage BV and specific on-resistance Rsp. On the other hand, higher requirements are also placed on the reliability of the device's high-current short-circuit capability.

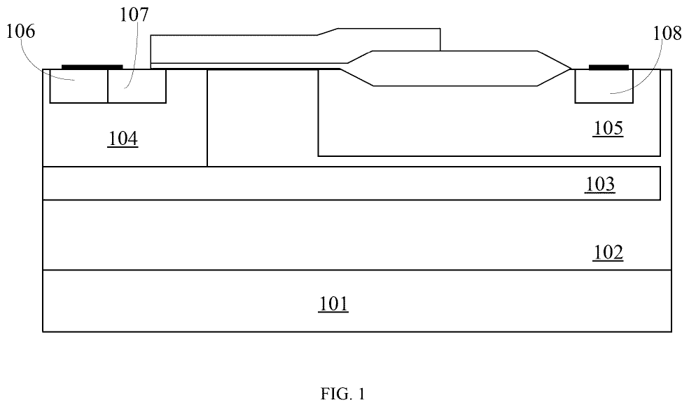

Referring now to FIG. 1, shown is a cross-sectional view of an example LDMOS transistor. This particular example LDMOS transistor can include substrate 101, semiconductor region 102 located on substrate 101, drift region 105 of a first doped type located in semiconductor region 102, body region 104 of a second doped type located in semiconductor region 102, drain region 108 located in drift region 105, and source region 107 and body contact region 106 located in body region 104. The LDMOS transistor can also include implant region 103 of the second doped type located below drift region 105. Implant region 103 can extend to below source region 107 and may be in contact with body region 104. Implant region 103 can be mutually depleted with drift region 105 to reduce the electric field at the transistor surface and significantly reduce the on-resistance of the transistor. However, when high current from drain region 108 causes minority carriers to flow through the surface channel of drift region 105 and body region 104 to body contact region 106, it can trigger turn-on of a parasitic NPN transistor (source region/body region/semiconductor region, source region/implant region/drift region), which can result in very poor high-current short-circuit capability of the LDMOS transistor.

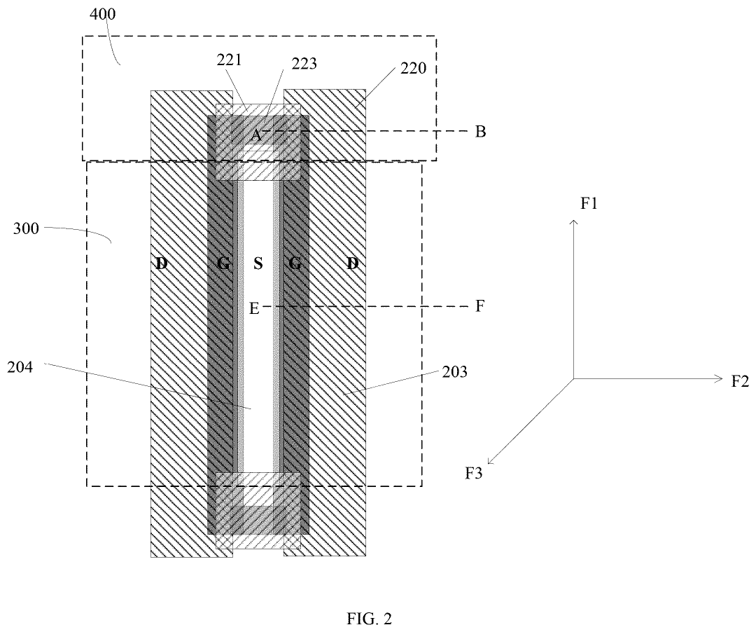

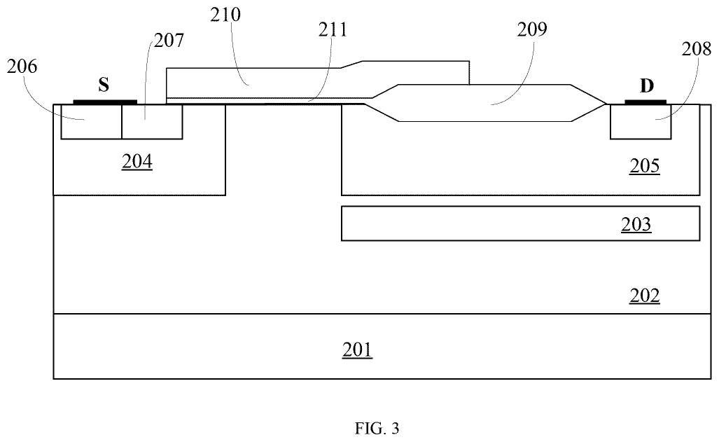

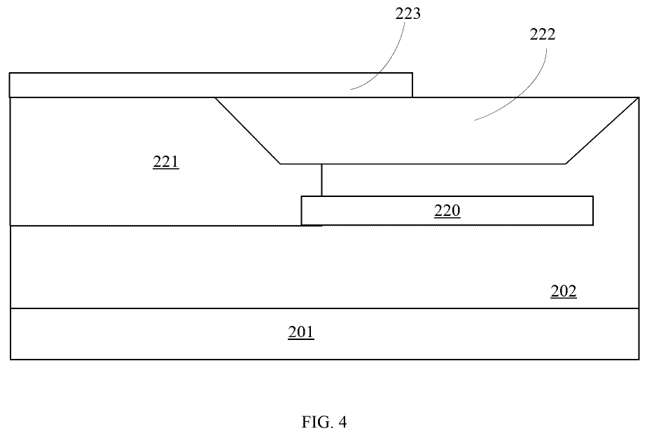

Referring now to FIG. 2, shown is a plan view of a first example LDMOS transistor, in accordance with embodiments of the present invention. Referring also to FIG. 3, shown is a cross-sectional view of an example intrinsic region of the first example LDMOS transistor, in accordance with embodiments of the present invention. Referring also to FIG. 4, shown is a cross-sectional view of an example termination region of the first example LDMOS transistor, in accordance with embodiments of the present invention. FIG. 3 is the structure along the axis E-F in FIG. 2, and FIG. 4 is the structure along the axis A-B in FIG. 2. As shown in FIG. 2, the LDMOS transistor can include intrinsic region 300 and termination region 400 distributed along direction F1.

As shown in FIG. 3, the intrinsic region can include semiconductor region 202 of a first doped type, body region 204 of a second doped type extending from the upper surface of the semiconductor region into the interior of the semiconductor region, a drift region located in semiconductor region 202 and including at least one implant region 205 of the first doped type and at least one implant region 203 of the second doped type, source region 207 of the first doped type located in body region 204, and drain region 208 of the first doped type located in semiconductor region 202.

Implant region 205 may be provided to increase the doping concentration of the semiconductor region, further reducing the specific on-resistance of the transistor. Additionally, implant region 203 can be mutually depleted with implant region 205, thereby reducing the surface electric field between the gate and drain of the transistor and improving the breakdown voltage of the transistor. Therefore, the shape, position, number, etc., of implant regions 203 and 205 are not limited in certain embodiments, as long as they can mutually deplete to optimize breakdown voltage and specific on-resistance. The first doped type is set to one of N-type and P-type, and the second doped type is set to the other of N-type and P-type.

As shown in FIG. 4, the termination region can include a third implant region of the second doped type being in contact with implant region 203. For example, the third implant region can include doped region 220 being in contact with implant region 203, and well region 221 being in contact with doped region 220. Well region 221 can be in contact with body region 204 of intrinsic region 300. For example, as shown in FIGS. 2 and 4, doped region 220 can be distributed along the first direction at both ends of implant region 203. For example, doped region 220 and implant region 203 can be regions of the same layer formed simultaneously. In addition, region 221 may be distributed along the first direction at both ends of body region 204.

The LDMOS transistor can also include body contact region 206 located in body region 204 and adjacent to source region 207. The direction from source region 207 to drain region 208 can be set as direction F2, and the direction from the lower surface of semiconductor region 202 to the upper surface of semiconductor region 202 set as direction F3, where directions F1, F2, and F3 are mutually perpendicular. In this particular example, implant region 205 of the first doped type and body region 204 of the second doped type can be separated. Also, implant region 203 of the second doped type and body region 204 of the second doped type can be arranged to be separated. This may reduce the flow of minority carriers from the drain side through implant region 203 and body region 204 of the intrinsic region to source region 207 and a body contact region 206, and can increase the flow of minority carriers from the drain side through the termination region 400 to source region 207 and body contact region 206.

In the example shown in FIG. 2, the LDMOS transistor can also include an insulating structure located at least on the upper surface of the semiconductor region between source region 207 and drain region 208. For example, the insulating structure can include gate dielectric layer 211 adjacent to the source region and insulating layer 209 adjacent to the drain region, and gate conductor 210 located at least on gate dielectric layer 211 and further extending onto part of insulating layer 209. Gate conductor 210 can include polysilicon material. Insulating layer 209 can be set as one or a combination of two of a thin dielectric layer, a thick dielectric layer (e.g., local oxidation of silicon [LOCOS], nitride layer, etc.), or a shallow trench isolation. For example, the thin dielectric layer can have the same thickness as the gate dielectric layer.

In particular embodiments, implant region 205 can be located at least below insulating layer 209. Implant region 205 is arranged to be in contact with the upper surface of semiconductor region 202. That is, implant region 205 can be arranged to be in contact with insulating layer 209, and drain region 208 may be located in implant region 205. Implant region 205 can be arranged at the surface of the semiconductor region, in order to increase the doping concentration at the surface of the semiconductor region. This can make carriers flowing from the drain to the source more inclined to flow along implant region 205, thus reducing the flow resistance and path of the carriers. In another example, implant region 205 may not contact with the upper surface of semiconductor region 202; that is, the upper surface of implant region 205 can be spaced a certain distance from the upper surface of the semiconductor region.

In particular embodiments, implant region 203 can be disposed below implant region 205, and implant regions 203 and 205 can mutually deplete more effectively. For example, the spacing between implant regions 203 and 205 can be greater than or equal to 0. In another example, implant regions 203 and 205 can be arranged side by side, or implant region 203 may surround implant region 205. The positional relationship between implant regions 203 and 205 is not limited in certain embodiments.

In particular embodiments, the number of layers for both implant regions 203 and 205 can be set to one. In another example, the number of layers for implant regions 203 and 205 can be set to multiple layers. Implant regions 203 and 205 can be alternately arranged along direction F3, or multiple implant regions 205 can be arranged adjacent to each other, multiple implant regions 203 may be arranged adjacent to each other, and the multiple implant regions 203 can be disposed below the multiple implant regions 205. For example, the spacing between adjacent implant regions 203 and 205 can be greater than or equal to 0.

Additionally, the LDMOS transistor can include substrate 201 of the second doped type. Semiconductor region 202 can be located in substrate 201, and the semiconductor region may of the first doped type and configured as a well region. In another example, the semiconductor region may be configured as an epitaxial layer of the first doped type on the substrate. Here, the body region and the drift region may both be located in the epitaxial layer, and the body region may be in contact with the first implant region, as long as ensured that the doping type of the semiconductor region surface between the source and drain (excluding the channel region) is the same as that of the drain region. In another example, an epitaxial layer and a buried layer between substrate 201 and the semiconductor region can be included.

In particular embodiments, the termination region can also include shallow trench isolation structure 222. Shallow trench isolation structure 222 can be in contact with insulating layer 209 of the intrinsic region, and conductor layer 223 located on part of well region 221 and part of the shallow trench isolation structure. Also, conductor layer 223 can be in contact with the gate conductor of the intrinsic region.

In particular embodiments, the breakdown voltage and specific on-resistance of the LDMOS transistor can be optimized by providing implant regions 203 and 205. Additionally, by arranging implant region 203 to be separated from the body region and providing the third implant region in the termination region, minority carriers from the drain side (e.g., taking the first dope type as N-type, the minority carriers are holes) may flow through implant region 203 to doped region 220 and well region 221 of the termination region, and finally to the source region and body contact region 206. This arrangement can significantly reduce the base current of the parasitic NPN in intrinsic region 300, suppress the turn-on of the parasitic NPN, and greatly improve the reliability under high-current short-circuit conditions.

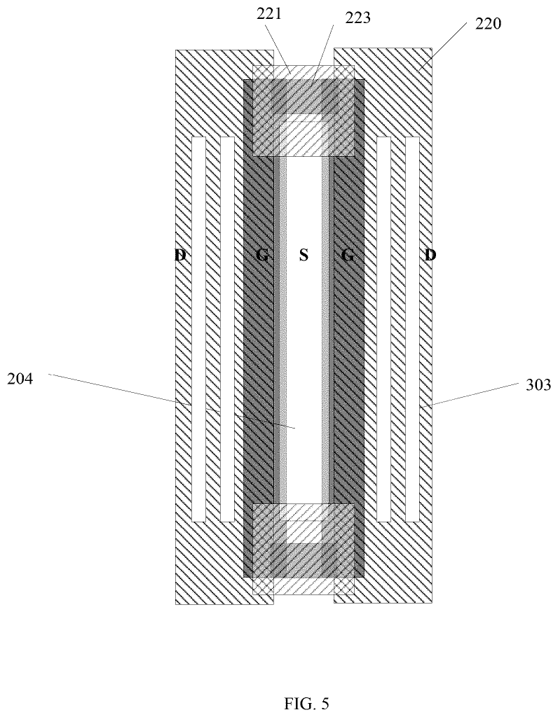

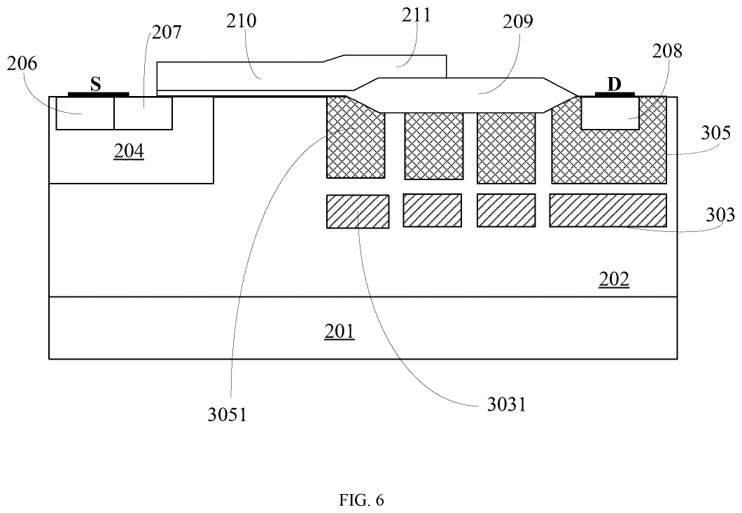

Referring now to FIG. 5, shown is a plan view of a second example LDMOS transistor, in accordance with embodiments of the present invention. Referring also to FIG. 6, shown is a cross-sectional view of an example intrinsic region of the second example LDMOS transistor, in accordance with embodiments of the present invention. The drift region can include at least one implant region 305 of the first dope type and at least one implant region 303 of the second dope type. Each layer of the “first” implant region 305 can include a plurality of separated first doped regions 3051. Each layer of the “second” implant region 303 can include a plurality of separated doped regions 3031.

In particular embodiments, both of implant regions 303 and 305 can be configured as one layer. The plurality of separated doped regions 3051 may be arranged along direction F2, the plurality of separated doped regions 3031 can be arranged along direction F2, and doped regions 3031 may be located below doped regions 3051. For example, one doped region 3031 may be provided below each doped region 3051. For example, the spacing between adjacent doped regions 303 and 305 in direction F3 can be greater than or equal to 0.

In particular embodiments, the spacing between adjacent doped regions 3051 may be the same, and the spacing between adjacent doped regions 3031 can also be the same. In another example, the spacing between adjacent doped regions 3051, as well as the width of each doped regions 3051, can be set arbitrarily according to particular requirements. The spacing between adjacent doped regions 3031, as well as the width of each doped region 3031, can be set arbitrarily according to particular requirements, in order to maximize the optimization of breakdown voltage and specific on-resistance, and to reduce the base current of the parasitic NPN and suppress its turn-on.

The structure in FIG. 3 is one example case of the structure in FIG. 6 when the spacing between the adjacent doped regions 3051 and the spacing between the adjacent doped regions 3031 are zero. The structure in FIG. 6 shows greater freedom to balance high-current short-circuit capability and the required specific on-resistance of the required device, particularly when the spacing between the adjacent doped regions 3051 is greater than the spacing between the adjacent doped regions 3031, implant region 203 can more completely deplete implant region 205.

In particular embodiments, a method for manufacturing an LDMOS transistor can also be provided, and the method may be applicable to the example LDMOS transistors of FIGS. 2 and 5, as just two examples. The method can include forming intrinsic region 300 and termination region 400 distributed along a first direction. The forming the intrinsic region can include forming semiconductor region 202 of a first doped type, forming body region 204 of a second doped type extending from the upper surface of the semiconductor region into the interior of the semiconductor region, forming a drift region located in the semiconductor region and that includes at least one implant region 205/305 of the first doped type and at least one implant region 203/303 of the second doped type, forming source region 207 of the first doped type located in body region 204, and forming drain region 208 of the first doped type located in semiconductor region 202.

The forming the termination region can include forming a third implant region of the second doped type in contact with implant region 203/303. The direction from source region 207 to drain region 208 can be set as a second direction, and the direction from the lower surface of the semiconductor region to the upper surface of the semiconductor region set as a third direction. For example, the first, second, and third directions (e.g., F1, F2, and F3, respectively) are mutually perpendicular. Implant region 203/303 can be arranged to be separated from body region 204, in order to reduce the flow of minority carriers from the drain side through the second implant region and the body region of the intrinsic region to the body contact region, and to increase the flow of minority carriers from the drain side through the termination region to the body contact region.

The forming the drift region located in the semiconductor region can include forming a mask including implant windows, using the first mask as a mask, forming at least one first implant region of the first doped type, and while using the second mask as a mask, forming at least one second implant region of the second doped type. The implant energy and dose can be adjusted to form first and second implant regions at different depths, and implant windows of the first mask and the second mask can be the same or different in certain embodiments.

When using the two masks with different implant windows to form implant region 205/305 and implant region 203/303, after forming implant region 205/305 and before forming implant region 203/303, the method can also include forming insulating layer 209 located above the drift region and on the surface of the semiconductor region. In this example, insulating layer 209 can be configured as a LOCOS layer formed by a locally thermal oxidation grown process. In other embodiments, insulating layer 209 can be a deposited silicon oxide layer and/or a deposited silicon nitride layer.

The forming the third implant region can include forming doped region 220 in contact with implant region 203/303, and forming well region 221 in contact with doped region 220. For example, well region 221 can be in contact with body region 204 of the intrinsic region. Also, well region 221 can be distributed along the first direction (e.g., F1) at both ends of body region 204, and doped region 220 is distributed along the first direction at both ends of implant region 203. When implant region 203 is configured as a continuous structure, e.g., implant region 203 and doped region 220 can be formed simultaneously. The method can also include forming gate dielectric layer 211 extending from the source region to insulating layer 209, and forming gate conductor 210 located at least on gate dielectric layer 211. For example, gate conductor 210 may extend from above gate dielectric layer 211 to at least above part of insulating layer 209.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A laterally-diffused metal-oxide-semiconductor (LDMOS) transistor, comprising:
a) an intrinsic region and a termination region distributed along a first direction;
b) wherein the intrinsic region comprises a semiconductor region of a first doped type;
c) wherein the intrinsic region comprises a body region of a second doped type extending from the upper surface of the semiconductor region into the interior of the semiconductor region;
d) wherein the intrinsic region comprises a drift region located in the semiconductor region, the drift region comprising at least one first implant region of the first doped type and at least one second implant region of the second doped type, wherein the at least one second implant region is separated from the body region;
e) wherein the intrinsic region comprises a source region of the first doped type located in the body region, and a drain region of the first doped type located in the semiconductor region;
f) wherein the termination region comprises a third implant region of the second doped type being in contact with the second implant region; and
g) wherein a direction from the source region to the drain region is set as a second direction, and the first direction and the second direction are mutually perpendicular.

2. The LDMOS transistor of claim 1, wherein each layer of the first implant region comprises a plurality of separated first doped regions distributed along the second direction.

3. The LDMOS transistor of claim 1, wherein each layer of the second implant region comprises a plurality of separated second doped regions distributed along the second direction.

4. The LDMOS transistor of claim 1, wherein the second implant region is disposed below the first implant region.

5. The LDMOS transistor of claim 1, wherein the first implant region is configured to be in contact with the upper surface of the semiconductor region.

6. The LDMOS transistor of claim 5, wherein the drain region is located in the first implant region.

7. The LDMOS transistor of claim 1, wherein:
a) when the first implant region or the second implant region comprises at least two layers, the first implant region and the second implant region are alternately distributed in a third direction; and
b) the third direction is configured as a direction from the lower surface of the semiconductor region to the upper surface of the semiconductor region.

8. The LDMOS transistor of claim 1, wherein the third implant region comprises:
a) a third doped region being in contact with the second implant region; and
b) a second well region being in contact with the third doped region, and being in contact with the body region of the intrinsic region.

9. The LDMOS transistor of claim 8, wherein the third doped region is distributed along the first direction at both ends of the second implant region, and the second well region is distributed along the first direction at both ends of the body region.

10. The LDMOS transistor of claim 1, wherein the intrinsic region further comprises:
a) an insulating structure located at least on the upper surface of the semiconductor
region between the source region and the drain region;
b) a gate conductor located on the insulating structure, and extending from the source region to at least above part of the drift region; and
c) wherein the insulating structure comprises a gate dielectric layer adjacent to the source region and a second insulating layer adjacent to the drain region.

11. The LDMOS transistor of claim 10, wherein the drift region is located at least below the second insulating layer.

12. The LDMOS transistor of claim 10, wherein the second insulating layer is set as one or a combination of two of: a thin dielectric layer, a voltage-blocking dielectric layer thicker than the gate dielectric layer, and a shallow trench isolation.

13. A method for manufacturing an LDMOS transistor, the method comprising:
a) forming an intrinsic region and a termination region distributed along a first direction;
a) wherein the forming the intrinsic region comprises forming a semiconductor region of a first doped type;
b) wherein the forming the intrinsic region comprises forming a body region of a second doped type extending from the upper surface of the semiconductor region into the interior of the semiconductor region;
c) wherein the forming the intrinsic region comprises forming a drift region located in the semiconductor region, the drift region comprising at least one first implant region of the first doped type and at least one second implant region of the second doped type, wherein the at least one second implant region is separated from the body region;
d) wherein the forming the intrinsic region comprises forming a source region of the first doped type located in the body region, and forming a drain region of the first doped type located in the semiconductor region;
e) wherein the forming the termination region comprises forming a third implant region of the second doped type being in contact with the second implant region; and
f) wherein a direction from the source region to the drain region is set as a second direction, and the first direction and the second direction are mutually perpendicular.

14. The method of claim 13, wherein the forming the drift region located in the semiconductor region comprises:
a) forming a first mask;
b) forming, by using the first mask as a mask, at least one first implant region of the first doped type;
c) forming a second mask; and
d) forming, by using the second mask as a mask, at least one second implant region of the second doped type.

15. The method of claim 14, wherein after the forming the first implant region and before forming the second implant region, the method comprises forming a second insulating layer located above the drift region and on the surface of the semiconductor region.

16. The method of claim 13, wherein the forming the third implant region comprises:
a) forming a third doped region being in contact with the second implant region;
b) forming a second well region being in contact with the third doped region, and being in contact with the body region of the intrinsic region.

17. The method of claim 16, wherein when the second implant region is configured as a continuous single-layer structure, the second implant region and the third doped region are formed simultaneously.
